(19) United States
(12) Patent Application Publication
(10) Pub. No.: US 2020/0103179 A1
(43) Pub. Date: Apr. 2, 2020

(54) ASSEMBLIES HAVING ENHANCED HEAT TRANSFER THROUGH VASCULAR CHANNELS AND METHODS OF MANUFACTURING ASSEMBLIES HAVING VASCULAR CHANNELS

(71) Applicant: GM GLOBAL TECHNOLOGY OPERATIONS LLC, Detroit, MI (US)

(72) Inventors: Anthony M. COPPOLA, Rochester Hills, MI (US); Alireza FATEMI, Canton, MI (US); Hamid G. KIA, Bloomfield Hills, MI (US)

(73) Assignee: GM GLOBAL TECHNOLOGY OPERATIONS LLC, Detroit, MI (US)

(21) Appl. No.: 16/148,634

(22) Filed: Oct. 1, 2018

(51) Int. Cl. F28F 1/40; B21C 23/08; B29B 11/10; B29C 70/68; H05K 7/20

(52) U.S. Cl. CPC F28F 1/40; B21C 23/08; B29B 11/10; B29C 70/683; B29L 2031/3481; H05K 7/20927; H05K 7/209; H05K 7/20854; H05K 7/20872; B29C 70/682

(57) ABSTRACT

A power module according to various aspects of the present disclosure includes a housing and a thermally-conductive element. The housing includes a polymer. The housing at least partially defines a channel. The channel is configured to receive a fluid. The thermally-conductive element is disposed at least partially within the housing. The thermally-conductive element is in fluid communication with the channel. The thermally-conductive element includes a thermally-conductive material. The thermally-conductive element is in thermal communication with the channel and a heat source. In certain aspects, includes at least one of a protrusion, a pin, and sheath. A method of manufacturing a channel having a thermally-conductive element for heat transfer includes (a) forming a channel, (b) forming a housing, and (c) removing a sacrificial material.

### INTRODUCTION

The present disclosure relates to assemblies having enhanced heat transfer through vascular channels and methods of manufacturing assemblies having vascular channels.

This section provides background information related to the present disclosure which is not necessarily prior art.

Traditionally, many components for automotive applications have been made of metals, such as steel and iron. Metals components are robust, typically having good ductility, durability, strength, and impact resistance. While metals have performed as acceptable vehicle components, they have a distinct disadvantage in being heavy and reducing gravimetric efficiency, performance, and power of a vehicle thereby reducing fuel economy of the vehicle.

Weight reduction for increased fuel economy in vehicles has spurred the use of various lightweight metal components, such as aluminum and magnesium alloys as well as use of light-weight reinforced composite materials. While use of such lightweight materials can serve to reduce overall weight and generally may improve fuel efficiency, issues can arise when using such materials in components that are exposed to high temperatures. For example, the lightweight metal components can also have relatively high linear coefficients of thermal expansion, as compared to traditional steel or ceramic materials. The use of such lightweight metals can cause uneven thermal expansion under certain thermal operating conditions relative to adjacent components having lower linear coefficients of thermal expansion, like steel or ceramic materials, resulting in separation of components and decreased performance. Additionally, performance of light-weight reinforced composite materials can decrease after continuous exposure to high temperatures.

### SUMMARY

This section provides a general summary of the disclosure, and is not a comprehensive disclosure of its full scope or all of its features.

In various aspects, the present disclosure provides a method of manufacturing a channel having a thermally-conductive element for heat transfer. The method includes (a) forming a channel, (b) forming a housing, and (c) removing a sacrificial material. The forming the channel includes (i) piercing a first channel precursor with a first plurality of thermally-conductive elements of a first thermally-conductive component to form a first intermediate assembly, the first channel precursor including a first sacrificial material, the first thermally-conductive component including a first thermally-conductive material; or (ii) piercing a second channel precursor with a plurality of second thermally-conductive elements to form a second intermediate assembly, the second channel precursor including a second sacrificial material, the second plurality of thermally-conductive elements including a second thermally-conductive material; or (iii) applying a third thermally-conductive element to a third channel precursor to form a third intermediate assembly, the third channel precursor including a third sacrificial material, the third thermally-conductive element including a third thermally-conductive material. The forming the housing includes placing the first, second, or third intermediate assembly in a respective first, second, or third mold. The forming the housing further includes introducing a housing precursor into the respective first, second, or third mold, the housing precursor including a polymer precursor. The forming the housing further includes solidifying the polymer precursor to form: (i) a first solid polymeric assembly including a first polymeric housing disposed around at least a portion of the first channel precursor; or (ii) a second solid polymeric assembly including a second polymeric housing disposed around at least a portion of the second channel precursor; or (iii) a third solid polymeric assembly including a third polymeric housing disposed around at least a portion of the third channel precursor. The removing includes (i) removing the first sacrificial material to form a first channel including the plurality of first thermally-conductive elements, wherein the first channel is defined in the first polymeric housing and the first thermally-conductive component; or (ii) removing the second sacrificial material to form a second channel including the plurality of second thermally-conductive elements, wherein the second channel is defined in the second polymeric housing; or (iii) removing the third sacrificial material to form a third channel including the third thermally-conductive element, wherein the third channel is defined in the third polymeric housing.

In one aspect, the housing precursor further includes at least one of a plurality of reinforcing fibers or a plurality of reinforcing particles.

In one aspect, the plurality of reinforcing fibers or the plurality of reinforcing particles is thermally conductive.

In one aspect, applying the third thermally-conductive element includes applying the third thermally-conductive material circumferentially around at least a portion of an outer surface of the third channel precursor.

In one aspect, the respective first, second, or third sacrificial material includes a material capable of one or more of: melting, vaporizing, combusting, and solubilizing.

In one aspect, the first, second, or third thermally-conductive material includes a metal material, a ceramic material, or a combination thereof.

In one aspect, the first plurality of thermally-conductive elements extend along at least a portion of a diameter of the first channel.

In one aspect, a first thermally-conductive element of the plurality of first thermally-conductive elements includes a protrusion; or second thermally-conductive element of the plurality of second thermally-conductive elements comprises a pin; or the third thermally-conductive element includes one or more of a coil, a braided tube, a mesh tube, a knitted tube, or a crocheted tube.

In one aspect, the first channel defines a diameter of greater than or equal to about 100 μm to less than or equal to about 10 mm; or the second channel defines a diameter of greater than or equal to about 100 μm to less than or equal to about 10 mm; or the third channel defines a diameter of greater than or equal to about 100 μm to less than or equal to about 10 mm.

In one aspect, the first channel has an open volume of at least about 40% of a total volume of the first channel; or the second channel has an open volume of at least about 40% of a total volume of the second channel; or the third channel has an open volume of at least about 40% of a total volume of the third channel.

In various aspects, the present disclosure provides a power module. The power module includes a housing and a thermally-conductive element. The housing includes a polymer. The housing at least partially defines a channel. The channel is configured to receive a fluid. The thermally-conductive element is disposed at least partially within the housing. The thermally-conductive element is in fluid communication with the channel. The thermally-conductive element includes a thermally-conductive material. The thermally-conductive element is in thermal communication with the channel and a heat source.

In one aspect, the power module further includes an electronic component and a heat spreader component. The heat spreader component is disposed within the housing. The heat spreader component is in thermal contact with the electronic component and the channel.

In one aspect, the housing includes a reinforced composite. The reinforced composite includes the polymer and at least one of (a) a plurality of reinforcing fibers or (b) a plurality of reinforcing particles. The plurality of reinforcing fibers or the plurality of reinforcing particles are thermally conductive.

In one aspect, the thermally-conductive element projects at least partially into the channel.

In one aspect, the thermally-conductive element and the housing cooperate to define the channel.

In one aspect, the channel defines a diameter of greater than or equal to about 100 μm to less than or equal to about 10 mm.

In one aspect, the channel includes an outer shell. The outer shell defines a wall thickness of greater than or equal to about 1 μm to less than or equal to about 1 mm. The outer shell includes a metal, a polymer, a polymeric composite, or a combination thereof.

In one aspect, the channel has an open volume of at least about 40% of a total volume of the channel.

In one aspect, the channel extends a longitudinal axis. The channel defines a cross-sectional shape substantially perpendicular to the longitudinal axis. The cross-sectional shape is selected from the group consisting of: a circular shape, a triangular shape, an elliptical shape, a rectangular shape, and a multipoint star shape.

In one aspect, the cross-sectional shape is selected from the group consisting of: the triangular shape, the rectangular shape, and the multipoint star shape.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIGS. 1A-1B are schematic views of a power module according to various aspects of the present disclosure; FIG. 1A is a perspective view; FIG. 1B is a cross-sectional view taken at line 1B-1B of FIG. 1A;

FIG. 2 is a sectional view of another power module according to various aspects of the present disclosure;

FIG. 3 is a sectional view of yet another power module according to various aspects of the present disclosure;

FIGS. 4A-4B are partial views of a vascular assembly having a cooling channel a plurality of protrusions according to various aspects of the present disclosure; FIG. 4A is a side sectional view; FIG. 4B is a top sectional view taken from line 4B-4B of FIG. 4A;

FIGS. 5A-5B are partial views of another vascular assembly having a cooling channel and a plurality of pins according to various aspects of the present disclosure; FIG. 5A is a side sectional view; FIG. 5B is a top sectional view taken from line 5B-5B of FIG. 5A;

FIGS. 6A-6B are partial views of a vascular assembly having a cooling channel according to various aspects of the present disclosure; FIG. 6A is a side sectional view; FIG. 6B is a top sectional view taken from line 6B-6B of FIG. 6A;

FIGS. 7-14 are partial sectional views of components defining channels having different thermally-conductive elements; FIG. 7 shows a thermally-conductive element extending partially into a channel according to various aspects of the present disclosure; FIG. 8 shows a thermally-conductive element defining a saw tooth shape according to various aspects of the present disclosure; FIG. 9 shows thermally-conductive elements defining different heights according to various aspects of the present disclosure; FIG. 10 shows a thermally-conductive element defining a hook shape according to various aspects of the present disclosure; FIG. 11 shows a thermally-conductive element defining an opening according to various aspects of the present disclosure; FIG. 12 shows a plurality of thermally-conductive elements defining different shapes and dimensions according to various aspects of the present disclosure; FIG. 13 shows a thermally-conductive element extending completely across a channel according to various aspects of the present disclosure; FIG. 14 shows a thermally-conductive element defining a groove according to various aspects of the present disclosure;

FIGS. 15-20 are sectional views of components having different cooling channel shapes according to various aspects of the present disclosure; FIG. 15 shows a channel having a substantially circular cross-section according to various aspects of the present disclosure; FIG. 16 shows a channel having a substantially triangular cross-section according to various aspects of the present disclosure; FIG. 17 shows a channel having a substantially rectangular cross-section according to various aspects of the present disclosure; FIG. 18 shows a channel having a substantially elliptical cross-section according to various aspects of the present disclosure; FIG. 19 shows a channel having a substantially star-shaped cross-section according to various aspects of the present disclosure; FIG. 20 shows a channel having another substantially star-shaped cross-section according to various aspects of the present disclosure;

FIG. 21 is a sectional view of a component defining a channel having a shell according to various aspects of the present disclosure;

FIGS. 22A-22B are related to a method of forming a channel precursor according to various aspects of the present disclosure; FIG. 22A is a schematic view of a extrusion apparatus for forming the channel; FIG. 22B is a sectional view of the component defining the channel;

FIGS. 23A-23E depict a method of manufacturing the vascular assembly of FIGS. 4A-4B according to various aspects of the present disclosure;

FIGS. 24A-24E depict a method of manufacturing the vascular assembly of FIGS. 5A-5B according to various aspects of the present disclosure;

FIGS. 25A-25E depict a method of manufacturing the vascular assembly of FIGS. 6A-6B according to various aspects of the present disclosure; and

FIGS. 26A-26B show a vascular assembly defining a channel in communication with a thermally-conductive element and being exposed to a heat source according to various aspects of the present disclosure; FIG. 26A is a perspective view of the component; and FIG. 26B is a perspective view portion of a thermally-conductive component defining the thermally-conductive elements.

Corresponding reference numerals indicate corresponding parts throughout the several views of the drawings.

### DETAILED DESCRIPTION

Example embodiments are provided so that this disclosure will be thorough, and will fully convey the scope to those who are skilled in the art. Numerous specific details are set forth such as examples of specific compositions, components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, elements, compositions, steps, integers, operations, and/or components, but do not preclude the presence or addition of one or more other features, integers, steps, operations, elements, components, and/or groups thereof. Although the open-ended term “comprising,” is to be understood as a non-restrictive term used to describe and claim various embodiments set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, the present disclosure also specifically includes embodiments consisting of, or consisting essentially of, such recited compositions, materials, components, elements, features, integers, operations, and/or process steps. In the case of “consisting of,” the alternative embodiment excludes any additional compositions, materials, components, elements, features, integers, operations, and/or process steps, while in the case of “consisting essentially of,” any additional compositions, materials, components, elements, features, integers, operations, and/or process steps that materially affect the basic and novel characteristics are excluded from such an embodiment, but any compositions, materials, components, elements, features, integers, operations, and/or process steps that do not materially affect the basic and novel characteristics can be included in the embodiment.

Any method steps, processes, and operations described herein are not to be construed as necessarily requiring their performance in the particular order discussed or illustrated, unless specifically identified as an order of performance. It is also to be understood that additional or alternative steps may be employed, unless otherwise indicated.

When a component, element, or layer is referred to as being “on,” “engaged to,” “connected to,” or “coupled to” another element or layer, it may be directly on, engaged, connected or coupled to the other component, element, or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various steps, elements, components, regions, layers and/or sections, these steps, elements, components, regions, layers and/or sections should not be limited by these terms, unless otherwise indicated. These terms may be only used to distinguish one step, element, component, region, layer or section from another step, element, component, region, layer or section. Terms such as “first,” “second,” and other numerical terms when used herein do not imply a sequence or order unless clearly indicated by the context. Thus, a first step, element, component, region, layer or section discussed below could be termed a second step, element, component, region, layer or section without departing from the teachings of the example embodiments.

Spatially or temporally relative terms, such as “before,” “after,” “inner,” “outer,” “beneath,” “below,” “lower,” “above,” “upper,” and the like, may be used herein for ease of description to describe one element or feature's relationship to another element(s) or feature(s) as illustrated in the figures. Spatially or temporally relative terms may be intended to encompass different orientations of the device or system in use or operation in addition to the orientation depicted in the figures.

Throughout this disclosure, the numerical values represent approximate measures or limits to ranges to encompass minor deviations from the given values and embodiments having about the value mentioned as well as those having exactly the value mentioned. Other than in the working examples provided at the end of the detailed description, all numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; approximately or reasonably close to the value; nearly). If the imprecision provided by “about” is not otherwise understood in the art with this ordinary meaning, then “about” as used herein indicates at least variations that may arise from ordinary methods of measuring and using such parameters. For example, “about” may comprise a variation of less than or equal to 5%, optionally less than or equal to 4%, optionally less than or equal to 3%, optionally less than or equal to 2%, optionally less than or equal to 1%, optionally less than or equal to 0.5%, and in certain aspects, optionally less than or equal to 0.1%.

In addition, disclosure of ranges includes disclosure of all values and further divided ranges within the entire range, including endpoints and sub-ranges given for the ranges.

Example embodiments will now be described more fully with reference to the accompanying drawings.

Composite vehicle components may benefit from enhanced cooling, particularly during exposure to a heat source or high-temperature environment. One method of cooling composite components is to circulate a heat-transfer fluid through vascular channels in the composite component. However, the efficacy of cooling via vascular channels may be limited by a thermal conductivity of the composite material surrounding the channel containing the heat-transfer fluid. A heat transfer rate between the composite and the heat-transfer fluid can be improved through use of a conductive reinforcement in the polymer of the composite (e.g., conductive reinforcing fibers or particles). In one example, continuous carbon fibers are included in a composite vehicle component. The composite has a thermal conductivity in a plane of the fibers and a low thermal conductivity through a thickness of the composite.

In various aspects, the present disclosure provides a vascular assembly having increased heat transfer through one or more vascular channels. The vascular assembly may include a housing that at least partially defines the channels. The housing may be formed from a low-thermal-conductivity material, such as a polymer. The channels are in direct fluid communication with one or more thermally-conductive elements (e.g., thermally-conductive protrusions or pins extending into the channel, or a thermally-conductive sheath at least partially surrounding the channel). The thermally-conductive elements are in thermal contact with both the heat source and the channel. Therefore, heat is transferred from the heat source to the heat-transfer fluid circulating through the channel via conduction. The thermally-conductive elements may extend at least partially into the channel, or may extend at least partially around a periphery of the channel. Heat transfer properties may be optimized by varying a cross-sectional shape of the channel; a shape, size, and/or distribution of the heat-transfer elements; heat-transfer fluid flow characteristics; and a composition of the housing material, by way of example. The vascular assembly may include additional features to increase heat transfer through the composite, such as heat spreaders (e.g., thermally-conductive heat spreader plates) and/or a conductive reinforcement phase (e.g., conductive fibers).

As described above, some vehicle components are frequently exposed to high temperatures. The high temperatures may be generated by an external heat source, such that the component is disposed within a high-temperature environment, or an internal heat source. The internal heat source is disposed at least partially within the composite component. The internal heat source can be any powered component that generates heat. For example, the internal heat source may be a resistor, a capacitor, an inductor, a processor, an engine control unit, a high-powered electronics module (e.g., a metal-oxide-semiconductor field-effect transistor (MOSFET), an insulated-gate bipolar transistor (IGBT)), a motor component, a portion of a motor component, an internal combustion engine, or a portion of an internal combustion engine.

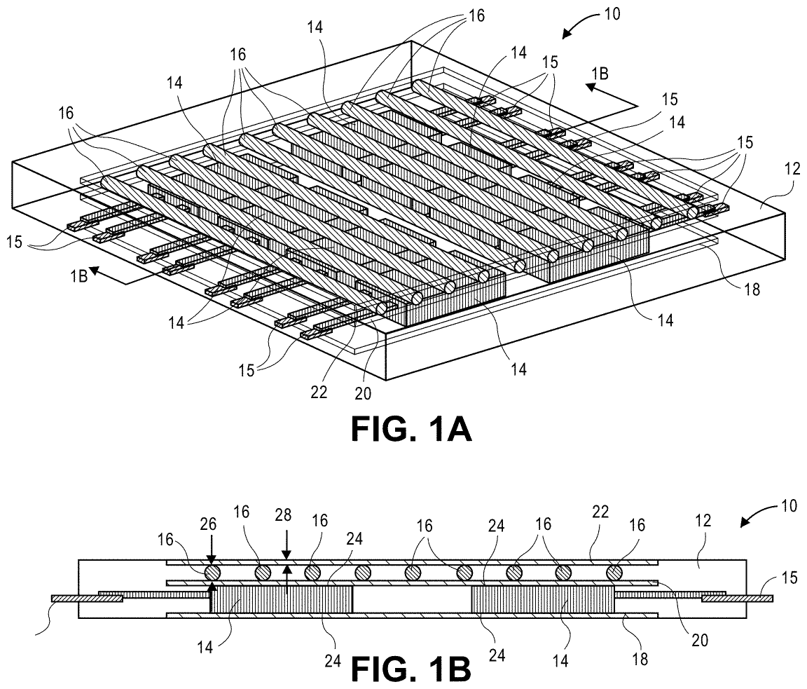

One example of a vehicle component that is exposed to heat is a power electronics module. With reference to FIG. 1, a power electronics module 10 according to various aspects of the present disclosure is provided. In various aspects, the power electronics module 10 may be referred to as a “vascular encapsulated power electronics module.” The power electronics module 10 includes a housing 12. The housing 12 may include a reinforced composite. A heat source, which may include a plurality of resistors 14, is disposed within the housing 12. The resistors 14 may be completely encapsulated within the housing 12. The resistors 14 may be electrically connected to an external power source (not shown) through electrical leads 15. The electrical leads 15 may be electrically connected to the resistors 14, such as by soldering.

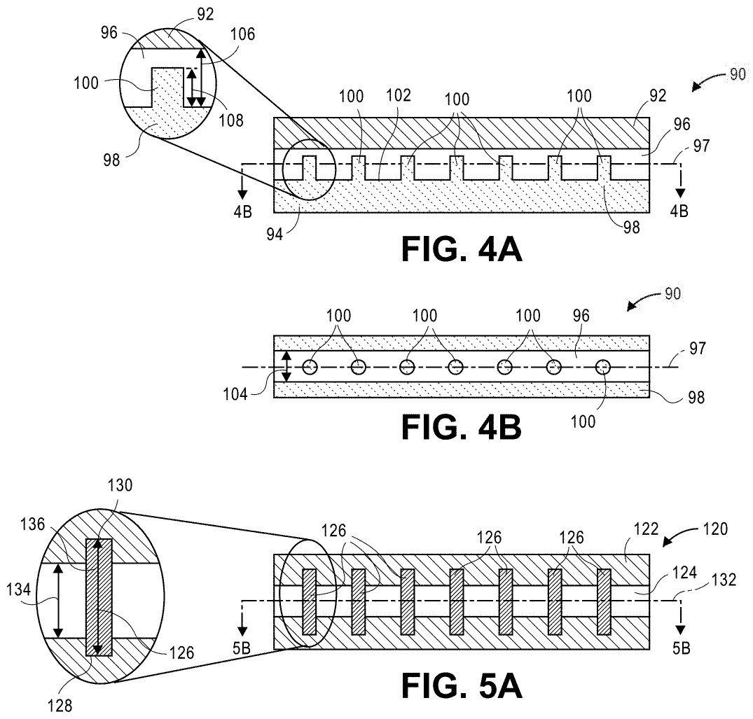

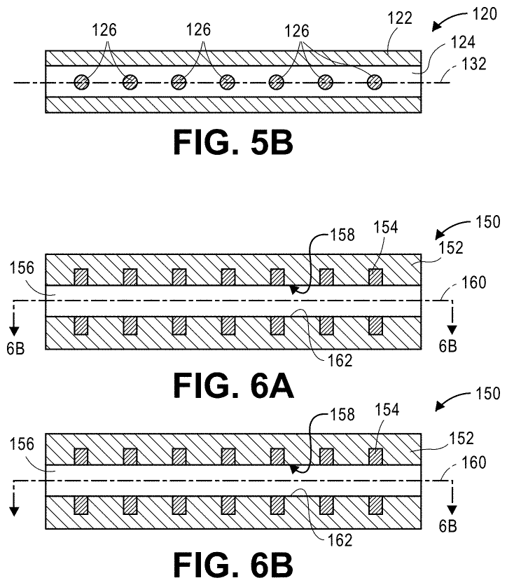

The housing 12 may define a plurality of channels 16. A heat-transfer fluid (not shown) may be circulated through the channels 16 to transfer heat away from the resistors 14. An external pump (not shown) may be used to circulate the heat-transfer fluid through the channels 16. The channels 16 may be fluidly connected to one another. In various alternative aspects, the housing may define a single channel that defines a serpentine shape (not shown). As will be discussed in greater detail below, the channel may include a plurality of thermally-conductive elements (not shown) to increase heat transfer between an electrical component and heat-transfer fluid in the channels 16 (see, e.g., protrusions 100 of FIGS. 4A-4B, pins 126 of FIGS. 5A-5B, and/or coil 154 of FIGS. 6A-6B).

The power electronics module 10 may further include first, second, and third heat spreader plates 18, 20, 22 to facilitate the transfer of heat away from the resistors 14. The heat spreader plates 18, 20, 22 may be formed from a thermally-conductive material (e.g., copper, aluminum). The resistors 14 may be disposed between the first heat spreader plate 18 and the second heat spreader plate 20. The resistors 14 may be fixed to the first and second heat spreader plates 18, 20 by adhesive (not shown) disposed between an external surface 24 of the resistors 14 and the first and second heat spreader plates 18, 20. The channels 16 may be disposed between the second heat spreader plate 20 and the third heat spreader plate 22.

The channels 16 may define substantially circular cross-sections in a direction substantially perpendicular to respective longitudinal axes of the channels 16. The substantially circular cross-sections may define a diameter 26. The heat spreader plates 18, 20, 22 may each define a thickness 28. In one example, the diameter 26 is about 1.8 mm and the thickness 28 is about 0.5 mm.

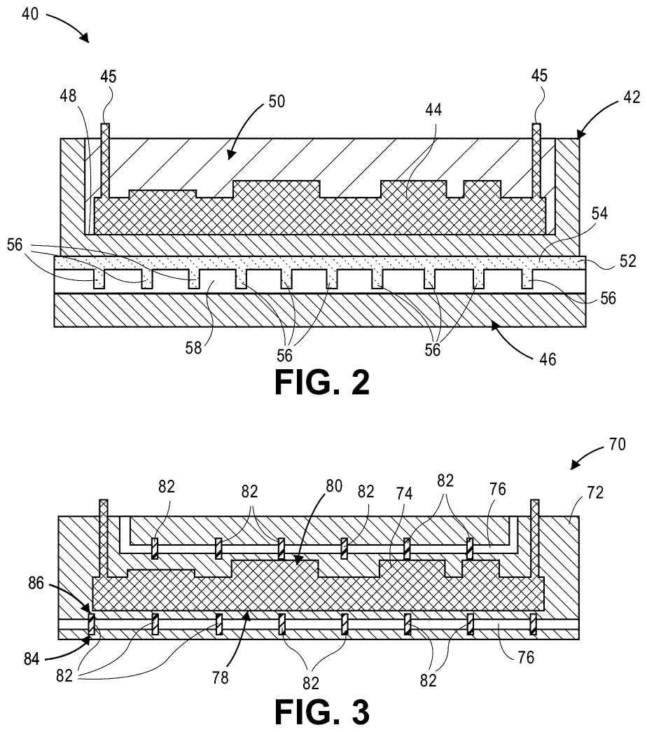

With reference to FIG. 2, another power electronics module 40 according to various aspects of the present disclosure is provided. The power electronics module 40 includes a housing 42. A heat source, which includes an electrical component 44 (e.g., a circuit board) is disposed within the housing 42. The electrical component 44 may be completely encapsulated within the housing 42. The electrical component 44 may be electrically connected to electrical leads 45 that extend at least partially outside of the housing 42. The housing 42 may include a reinforced composite portion 46 that at least partially defines a compartment 48 in which the electrical component 44 is disposed. The electrical component 44 may be encapsulated within the housing 42 by a flexible polymer portion 50 of the housing 42.

The power electronics module 40 may further include a thermally-conductive component 52. The thermally-conductive component 52 may include a body 54 and a plurality of protrusions 56. The reinforced composite portion 46 of the housing 42 may cooperate with the thermally-conductive component 52 to define a channel 58 through which a heat-transfer fluid (not shown) can be circulated. The thermally-conductive component 52 has a higher thermal conductivity than the reinforced composite portion 46 of the housing 42, and may therefore improve heat transfer to the heat-transfer fluid in the channel 58. Additionally, protrusions 56 increase contact between the thermally-conductive component 52 and the heat-transfer fluid to increase a rate of cooling of the housing 42 and improve performance of the power electronics module 40.

Referring to FIG. 3, yet another power electronics module 70 according to various aspects of the present disclosure is provided. The power electronics module 70 includes a housing 72. The housing 72 may be formed from a reinforced composite. A heat source, which may be an electrical component 74 (e.g., a circuit board) is disposed at least partially within the housing 72.

The housing 72 defines channels 76 through which a heat-transfer fluid (not shown) can be circulated to transfer heat away from the electrical component 74. The channels 76 may be disposed on both a first side 78 and a second side 80 of the electrical component 74. A plurality of pins 82 may extend through the channels 76. The pins 82 may be made from a thermally-conductive material. Each pin 82 includes a first end 84 and a second end 86 opposite the first end 84. The first and second ends 84, 86 may each extend into the housing 72 on opposing sides of the channel 76. The pins 82 may increase conductive heat transfer between the housing 72 and the heat-transfer fluid in the channel 76. In various aspects, the reinforced composite may include thermally-conductive reinforcing fibers or particles to facilitate the transfer of heat from the electrical component 74, through the housing 72, and to the heat-transfer fluid in the channel 76.

Vascular Assemblies

As described above in the context of power electronics modules 10, 40, 70, a vascular assembly according to various aspects of the present disclosure generally includes a housing at least partially defining one or more channels. The housing is exposed to a heat source, which may be internal or external to the vascular assembly. The channels include one or more thermally-conductive elements (which may also be referred to as “heat-transfer elements” or “heat-transfer features”). The thermally-conductive elements are in fluid communication with the channel to increase heat transfer from the housing to a heat-transfer fluid circulating within the channel. The thermally-conductive elements are in thermal communication with the heat-transfer fluid and the heat source. In the case of an internal heat source, channels may be disposed on a single side of the heat source (see, e.g., FIGS. 1A-2) or multiple sides of the heat source (see, e.g., FIG. 3). The power electronics module may further include one or more heat spreaders (e.g., heat spreader plates) and/or a plurality of conductive fibers or particles to improve conduction through the housing.

Housing

The housing may be formed from a material that provides sufficient structural integrity for the particular application. Suitable materials may include polymers, including reinforced composites, and metals. A reinforced composite includes a polymer matrix and a plurality of reinforcing fibers or particles.

A suitable polymer has a glass transition temperature that is greater than a maximum temperature to which the housing will be exposed during use. Suitable polymers include, but are not limited to a thermoset resin, a thermoplastic resin, elastomer, and combinations thereof. For example, polymers can include, epoxies, phenolics, vinylesters, bismaleimides, polyether ether ketone (PEEK), polyamides, polyimides, polyamideimides, and combinations thereof.

In various aspects, the housing may include the polymer and be free of any reinforcing fibers or reinforcing particles. In various alternative aspects, the housing may be formed from a reinforced composite including a polymer as described above and a plurality of reinforcing fibers or particles. Examples of suitable reinforcing fibers include glass fibers, aramid fibers, polyethylene fibers, organic fibers, metallic fibers, ceramic fibers, basalt fibers, quartz fibers, graphite fibers, nanofibers, boron fibers, and combinations thereof. In various aspects, the reinforcing fibers or particles are thermally conductive. Examples of suitable reinforcing particles include glass beads, glass microbubbles, calcium carbonate, silica, talc, alumina, and clay. Thermally-conductive fibers and particles can include carbon (e.g., carbon fibers), boron nitride, aluminum, alumina, carbon nanotubes, graphene, silica, aluminum nitride, magnesium oxide, by way of example. The reinforcing fibers may be continuous fibers and/or discontinuous fibers.

Suitable metals include aluminum, copper, stainless steel, steel, magnesium, gold plated materials, chromium plated materials, nickel, titanium, tungsten, tin, zinc, and alloys thereof. The housing may be formed entirely from polymer, reinforced composite, or metal. In various aspects, the housing may be formed from a combination of polymer, reinforced composite, and metal. For example, the housing may be formed from a combination of one or more polymer portions, one or more reinforced composite portions, and/or one or more metal portions (see, e.g., power electronics module 40 of FIG. 2, which includes the reinforce composite portion 46 and the flexible polymer portion 50).

Heat-Transfer Fluid

The heat-transfer fluid may be circulated through channels that are at least partially defined by the housing to transfer heat away from the heat source and in certain aspects, out of the housing. Examples of suitable heat-transfer fluids include, air, water, oil, ethylene glycol, propylene glycol, glycerol, methanol, and combinations thereof.

Thermally-Conductive Elements and Heat Spreaders

As described above, the vascular assembly includes one or more thermally-conductive elements in fluid communication with the channel, and optionally, one or more heat spreaders. The thermally-conductive elements and heat spreaders may be distinct components; the thermally-conductive elements may be assembled to the heat spreaders; or the thermally-conductive elements may be integrally formed with the heat spreaders. The thermally-conductive elements and the heat spreaders may be formed from the same material or from different materials. Heat spreaders may be plate-shaped or define other geometries.

The thermally-conductive components are formed from thermally-conductive materials. Thermally-conductive materials include copper, aluminum, stainless steel, steel, magnesium, gold plated materials, chromium plated materials, nickel, titanium, tungsten, tin, zinc, and alloys thereof; ceramic; composites including one or more polymers and thermally-conductive particles or fibers therein; and combinations thereof, by way of example. In various aspects, the thermally-conductive material includes aluminum, copper, or a combination thereof. The thermally-conductive elements can be formed from a single thermally-conductive material or a combination of thermally conductive materials. In one example, each of the thermally-conductive elements is formed from copper. In another example, a first portion of the thermally-conductive elements include copper and a second portion of the thermally-conductive elements include aluminum. In yet another example, each thermally-conductive element includes a copper portion and an aluminum portion. The heat spreaders may be formed from the same material or different materials. In one example, the vascular assembly includes three heat spreaders that are each formed from aluminum. In another example, the vascular assembly includes a copper heat spreader and an aluminum heat spreader.

The thermally-conductive material has a higher thermal conductivity than the material of housing (e.g., polymer). A thermal conductivity ratio of a thermally-conductive material (e.g., of the thermally-conductive element) to a housing material may be greater than or equal to about 10, optionally greater than or equal to about 25, optionally greater than or equal to about 50, optionally greater than or equal to about 40, optionally greater than or equal to about 100, optionally greater than or equal to about 250, optionally greater than or equal to about 500, and optionally greater than or equal to about 1000. In one example, the housing is formed from a material having a thermal conductivity of about 0.2 W/m·K, and the thermally-conductive elements are formed from a material having a thermal conductivity of about 2 W/m·K. In another example, the housing is formed from a material having a thermal conductivity of about 0.2 W/m·K, and the thermally-conductive elements are formed from a material having a thermal conductivity of about 200 W/m·K. In various aspects, the thermally-conductive elements may be formed from a material having a thermal conductivity of greater than or equal to about 8 W/m·K, optionally greater than or equal to about 10 W/m·K, optionally greater than or equal to about 20 W/m·K, optionally greater than or equal to about 50 W/m·K, optionally greater than or equal to about 100 W/m·K, optionally greater than or equal to about 150 W/m·K, and optionally greater than or equal to about 250 W/m·K.

Configuration of Channel and Thermally-Conductive Elements

The thermally-conductive elements may have any geometry that facilitates fluid communication between the heat-transfer fluid in the channel and the heat source. The thermally-conductive elements may be in direct fluid communication with the channel. In various aspects, the thermally-conductive element may extend into the channel. In various aspects, the thermally-conductive element may at least partially surround and define the channel. For example, the thermally-conductive element may include a plurality of protrusions (FIGS. 4A-4B), a plurality of pins (FIGS. 5A-5B), and/or a sheath (e.g., a coil, a braided tube, a mesh tube, a knitted tube, a crocheted tube, or the like) (FIGS. 6A-6B).

The thermally-conductive elements may be distributed along at least a portion of a length of the channel. In one example, the thermally-conductive elements are distributed along an entire length of the channel. In another example, the thermally-conductive elements are only present within the channel in an area near the heat source. In various aspects, the thermally-conductive elements may be evenly spaced across the length of the channel. In various alternative aspects, the thermally-conductive elements may be unevenly distributed within the channel. For example, a first portion of thermally-conductive elements may be disposed close to one another near the heat source, and a second portion of thermally-conductive elements may be spaced apart further from the heat source.

The channel defines a total volume without the thermally-conductive element. The thermally-conductive elements occupy an element volume within the channel. An open volume of the channel is a percentage of the total volume occupied by the thermally-conductive elements. The open volume may be greater than or equal to about 40%, optionally greater than or equal to about 45%, optionally greater than or equal to about 50%, optionally greater than or equal to about 55%, and optionally greater than or equal to about 60%.

Protrusions (FIGS. 4A-4B)

With reference to FIGS. 4A-4B, a portion of a vascular assembly 90 according to various aspects of the present disclosure is provided. The vascular assembly includes a housing 92 and a thermally-conductive component 94. The housing 92 and the thermally-conductive component 94 cooperate to at least partially define a channel 96 through which a heat-transfer fluid (not shown) may be circulated. The channel 96 defines a longitudinal axis 97.

The thermally-conductive component 94 includes a body 98 and a plurality of protrusions 100. In various aspects, the body 98 may be referred to as a “heat transfer plate.” The plurality of protrusions 100 are thermally-conductive elements. In various aspects, the protrusions 100 may also be referred to as “projections” or “spikes.” In one example, commercial GRIP Metal™ is used as the thermally-conductive component.

The protrusions 100 extend from a surface 102 of the body 98 and into the channel 96. The surface 102 may be planar or non-planar. In various aspects, the protrusions 100 are centered with respect to a width 104 of the channel 96. Thus, when the cross-section of the channel 96 perpendicular to the longitudinal axis 97 defines a substantially circular shape, the protrusions 100 may extend along at least a portion of a diameter 106 of the channel 96. In various alternative aspects, the protrusions 100 may extend across a non-diameter chord of the cross-sectional shape.

The protrusions 100 may be circumferentially aligned with one another. However, in alternative aspects, the protrusions 100 may be distributed about at least a portion of a circumference of the channel 96 (not shown). Furthermore, the channel 96 may include more than one protrusion 100 at a single location along the longitudinal axis 97 (not shown). For example, a pair of protrusions may extend toward one another along the diameter 106 of the channel 96.

The channel 96 defines a dimension, such as the diameter 106, substantially perpendicular to the longitudinal axis 97. The protrusions 100 define a height 108 substantially parallel to the diameter 106. In various aspects, a ratio of diameter 106 to height 108 may be greater than or equal to about 0.1 to less than or equal to about 1, optionally greater than or equal to about 0.2 to less than or equal to about 0.9, optionally greater than or equal to about 0.3 to less than or equal to about 0.8, optionally greater than or equal to about 0.4 to less than or equal to about 0.7, and optionally greater than or equal to about 0.5 to less than or equal to about 0.6.

Pins (FIGS. 5A-5B)

With reference to FIGS. 5A-5B, another vascular assembly 120 according to various aspects of the present disclosure is provided. The vascular assembly 120 includes a housing 122 that defines a channel 124 through which a heat-transfer fluid (not shown) may be circulated. The vascular assembly 120 further includes a plurality of pins 126. The pins 126 are thermally-conductive elements and are formed from a thermally-conductive material, as described above. Each pin 126 includes a first end 128 and a second end 130 opposite the first end 128. The first and second ends 128, 130 are embedded in the housing 122. Thus, each pin 126 is coupled to the housing 122 at two locations. In various aspects, when the pin 126 is coupled to the housing 122 at two locations, as shown, it may be referred to as a “column.” In various alternative aspects, pins may be coupled to the housing at a single location and extend at least partially across the channel 124 (e.g., along at least a portion of a diameter of the channel 124) (not shown).

The channel 124 may define a longitudinal axis 132 along a length of the channel 124. The channel 124 may define a dimension, such as a diameter 134 in the case of a channel defining a circular cross-section, perpendicular to the longitudinal axis 132. The pins 126 may extend along the diameter 134. In alternative embodiments, the columns 126 may extend along non-diameter chords.

The first ends 128 of the pins 126 are aligned with one another along the longitudinal axis 132 such that they are each disposed at the substantially the same circumferential location. The second ends 130 of the pins 126 are aligned with one another along the longitudinal axis 132 such that they are each disposed at the substantially the same circumferential location. In alternative aspects, the pins 126 may be disposed at different circumferential locations. For example, a first pin may be rotated about the longitudinal axis 132 with respect to a second pin (not shown).

Each pin 126 may define a height 136. The pins 126 may have the same heights or different heights. In various aspects, a ratio of the diameter 134 to the height 136 may be greater than about 1 to less than or equal to about 10, optionally greater than about 1.5 to less than or equal to about 8, optionally greater than about 2 to less than or equal to about 6, and greater than about 3 to less than or equal to about 4.

Sheath (FIGS. 6A-6B)

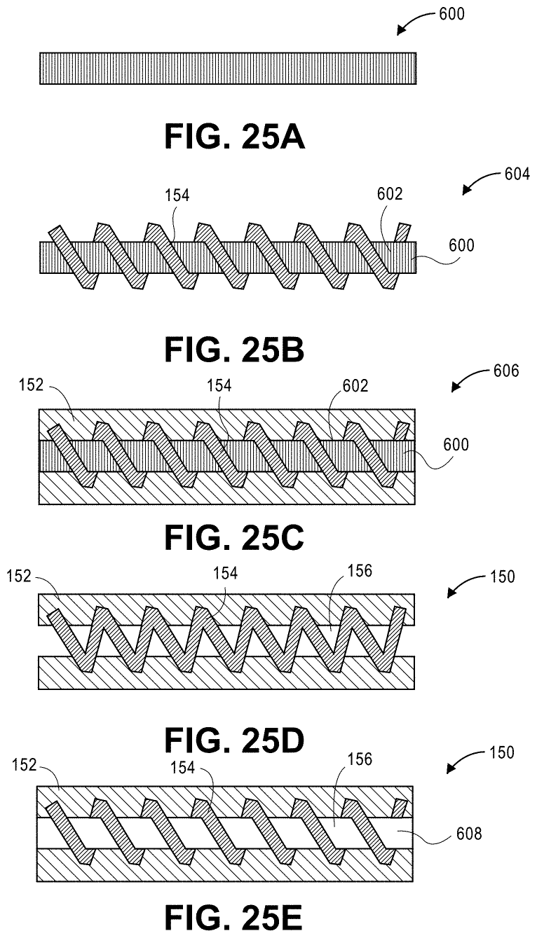

Referring to FIGS. 6A-6B, yet another vascular assembly 150 according to various aspects of the present disclosure is provided. The vascular assembly 150 includes a housing 152. The vascular assembly 150 further includes a sleeve or sheath, which may be a coil 154 (see also FIGS. 25B-25E). The coil 154 is a thermally-conductive element that is formed from a thermally-conductive material, as described above. In various alternative aspects, the sheath may include a braided, knitted, crocheted, or mesh tube. In various alternative aspects, the sheath may include a plurality of circumferential rings. In various alternative aspects, the sheathing could be extruded, cast, or sprayed on the tube.

The coil 154 and the housing 152 cooperate to at least partially define a channel 156 through which a heat-transfer fluid can be circulated. The channel defines a longitudinal axis 160. The coil 154 wraps around at least a portion of a periphery 158 of the channel 156 to form a portion of a surface 162 of the channel 156. In various alternative aspects, the coil 154 may extend at least partially into the channel 156 toward the longitudinal axis 160. Thus, the coil 154 may define “fins” (not shown). Any of the sheaths described above may extend at least partially into the channel 156 to define fins, corrugation, and/or texture.

Thermally-Conductive Element Geometries (FIGS. 7-14)

Thermally-conductive elements according to various aspects of the present disclosure may define a variety of different geometries. More particularly, thermally-conductive elements may define a variety of shapes, sizes, and distribution to optimize the rate of heat transfer and fluid flow characteristics. In general, increasing a surface area of the thermally-conductive elements will result in an increased rate of heat transfer between the thermally-conductive element and a heat-transfer fluid flowing through a channel. Increasing a roughness of the surface of all the thermally-conductive element may facilitate turbulent flow of the heat-transfer fluid. Turbulent flow of the heat-transfer fluid can result in an increase in the rate of heat transfer between the thermally-conductive elements and the heat-transfer fluid.

With reference to FIG. 7, a thermally-conductive element includes a protrusion 180 defining a substantially cylindrical shape. Thus, the protrusion 180 has a substantially uniform diameter along its length. The protrusion 180 extends from a body 182 of a thermally-conductive component 184 into a channel 186. The body 182 and a housing 188 cooperate to at least partially define the channel 186.

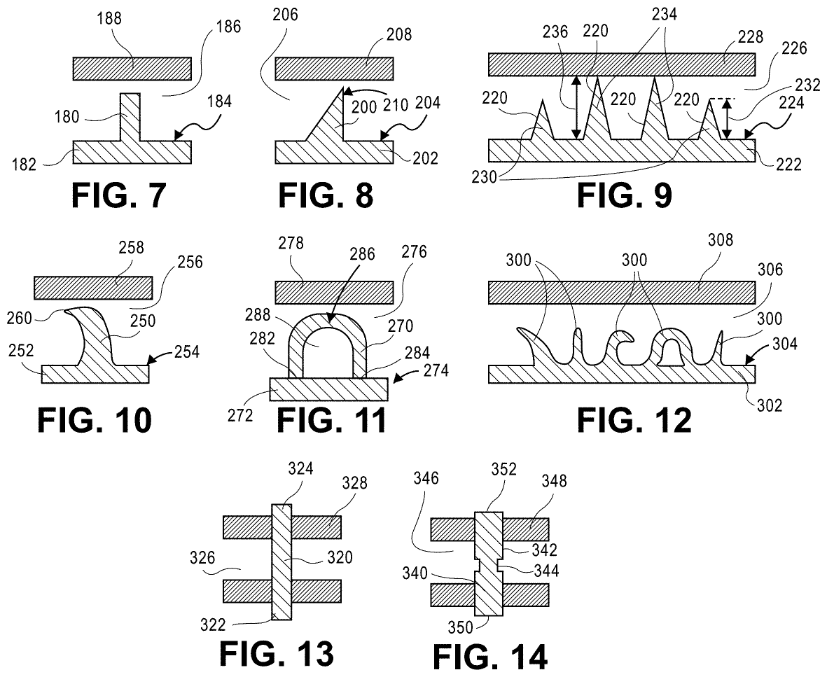

Referring to FIG. 8, a thermally-conductive element includes a protrusion 200 defining a substantially saw-tooth shape. The protrusion 200 extends from a body 202 of a thermally-conductive component 204 into a channel 206. The body 202 and a housing 208 cooperate to at least partially define the channel 206. The protrusion may include a pointed distal end 210.

With reference to FIG. 9, a thermally-conductive element includes a plurality of protrusions 220 defining cones. The protrusions 220 extend from a body 222 of a thermally-conductive component 224 into a channel 226. The body 222 and a housing 228 cooperate to at least partially define the channel 226. A first portion 230 of the protrusions 220 defines a first height 232. A second portion 234 of the protrusions defines a second height 236. The second height 236 is greater than the first height 232. Thus, a plurality of thermally-conductive elements according to various aspects of the present disclosure need not define uniform dimensions.

Referring to FIG. 10, a thermally-conductive element includes a protrusion that defines a hook 250. The hook 250 extends from a body 252 of a thermally-conductive component 254 into a channel 256. The body 252 cooperates with a housing 258 to define the channel 256. The hook 250 includes a distal end 260 that curves back on itself to point toward the body 252.

With reference to FIG. 11, a thermally-conductive element according to various aspects of the present disclosure is provided. The thermally-conductive element includes a protrusion that defines an arch 270. The arch 270 extends from a body 272 of a thermally-conductive component 274 into a channel 276. The body 272 cooperates with a housing 278 to define the channel 276. The arch 270 extends between a first end 282 and a second end 284. The arch 270 defines a curved portion 286 disposed between the first end 282 and the second end 284. The arch 270 defines a passage 288 through which heat-transfer fluid may flow.

Referring to FIG. 12, a plurality of thermally-conductive elements according to various aspects of the present disclosure is provided. The plurality of thermally-conductive elements includes a plurality of non-uniform protrusions 300. The protrusions 300 extend from a body 302 of a thermally-conductive component 304 into a channel 306. The body 302 cooperates with a housing 308 to at least partially define the channel 306.

With reference to FIG. 13, a thermally-conductive element according to various aspects of the present disclosure includes a column or pin 320. The column 320 includes a first end 322 and a second end 324 opposite the first end 322. The pin 320 extends through a channel 326 defined by a housing 328. Each of the first end 322 and the second and 324 of the pin 320 extends into the housing 328. The pin 320 defines a substantially cylindrical shape. Therefore, the pin 320 has a substantially uniform diameter.

Referring to FIG. 14, a thermally-conductive element according to various aspects of the present disclosure includes the column or pin 340. An outer surface 342 of the column 340 defines a groove 344. The groove 344 may be a circumferential groove. The presence of the groove 344 may increase a surface area of the pin 340 that is in contact with a heat-transfer fluid and improve heat transfer between the thermally-conductive element and the heat-transfer fluid. The pin 340 extends through channel 346 defined by housing 348. More particularly, a first end 350 and a second end 352 of the pin 340 each extend into the pin 340. Therefore, thermally-conductive elements according to various aspects of the present disclosure may define surface features to increase the surface area of the thermally-conductive element or affect flow characteristics of the heat-transfer fluid. Examples of other surface features include dimples, protrusions, circumferential ribs, axial grooves, and other textures.

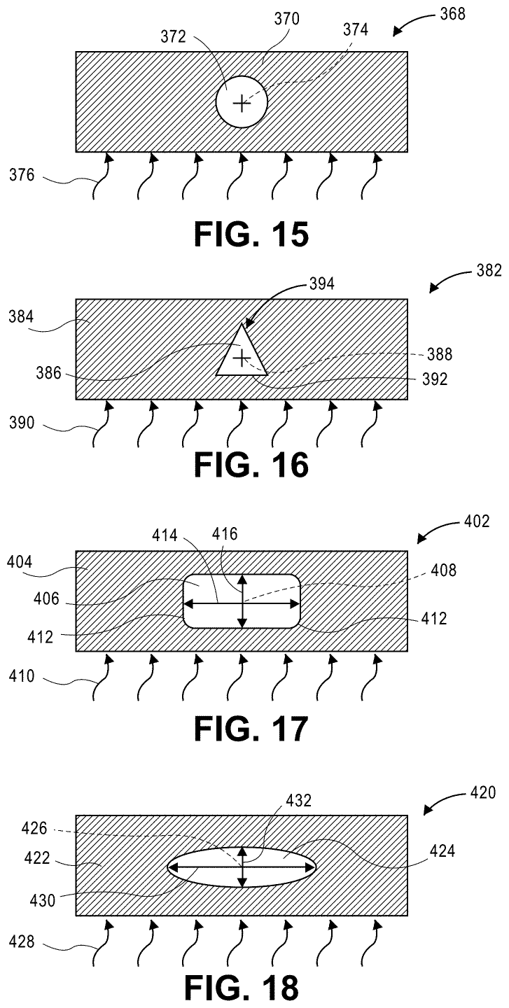

Channel Geometries (FIGS. 15-21)

Channels in vascular assemblies according to various aspects of the present disclosure may define a variety of shapes, sizes, and surface textures. In one example a housing surface defining a channel may have increased roughness, thereby facilitating turbulent flow of the heat-transfer fluid and increasing heat transfer between the thermally-conductive element and the heat-transfer fluid. A cross-sectional shape channel may be modified to optimize the rate of heat transfer, pressure drop across the channel, and structural performance of the vascular assembly. Increasing a dimension of the channel may result in increased rate of heat transfer. Increasing a perimeter of a cross-sectional shape of the channel, for example by adding convex or concave portions, particular adjacent to a heat source, may increase the rate of heat transfer.

The structural integrity of a vascular assembly defining a channel may be affected by a geometry of a cross-section of the channel perpendicular to a longitudinal axis of the channel. In various aspects, a strength of the vascular assembly having the channels is greater than or equal to 90% of the strength of the similar component without channels, optionally greater than or equal to 91%, optionally greater than or equal to 92%, optionally greater than or equal to 93%, optionally greater than or equal to 94%, optionally greater than or equal to 95%. In various aspects, a stiffness of the vascular assembly having the channels is greater than or equal to 90% of the strength of the similar component without channels, optionally greater than or equal to 91%, optionally greater than or equal to 92%, optionally greater than or equal to 93%, optionally greater than or equal to 94%, optionally greater than or equal to 95%. In various aspects, a fracture toughness of the vascular assembly having the channels is greater than or equal to 90% of the strength of the similar component without channels, optionally greater than or equal to 91%, optionally greater than or equal to 92%, optionally greater than or equal to 93%, optionally greater than or equal to 94%, optionally greater than or equal to 95%.

The cross-sectional size and shape of the channel also affect pressure drop across the channel. For example changing a size and/or shape of the channel can affect a hydraulic diameter of the channel, thereby changing the pressure drop across the channel. An acceptable pressure drop may be determined based on a size of pump to be used to circulate heat-transfer fluid through the vascular assembly. In various aspects, the pressure drop across the channel may be less than or equal to about 100 pounds per square inch (psi), optionally less than or equal to about 2 psi, optionally less than or equal to 1.5 psi, optionally less than or equal to 1 psi, and optionally less than or equal to 0.5 psi.

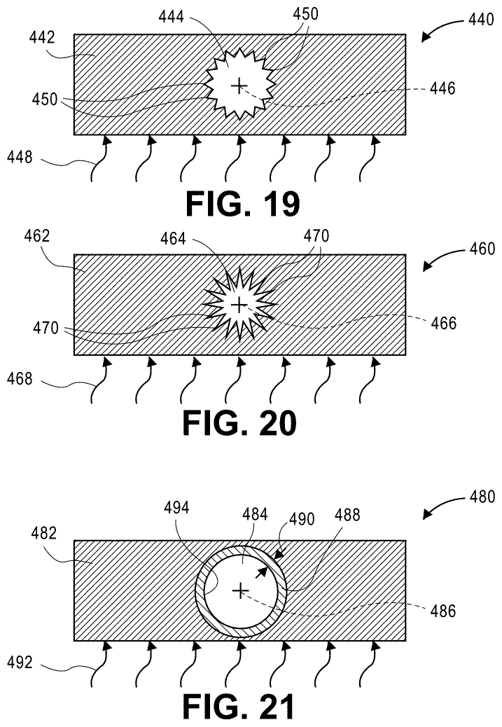

A channel according to various aspects of the present disclosure may define any cross-sectional channel shape that results in a channel having acceptable heat transfer properties, structural characteristics, fluid flow properties, and structural integrity. Examples of cross-sectional shape include an ellipse (FIG. 18), such as a circle (FIG. 15); a triangle (FIG. 16); a quadrilateral, such as a rectangle (FIG. 17), or a square (not shown); polygons having five or more sides, such as stars having five or more points (FIGS. 19-20). Additionally, channel may include a shell or coating (FIG. 21).

The cross-sectional shape may define a maximum dimension (e.g., a diameter when the cross-sectional shape is a circle). In various aspects, the maximum dimension may be greater than or equal to about 100 μm to less than or equal to about 10 mm, optionally greater than or equal to about 0.2 mm to less than or equal to about 5 mm, optionally greater than or equal to about 0.3 mm to less than or equal to about 3 mm, and optionally greater than or equal to about 0.5 to less than or equal to about 2 mm.

With reference to FIG. 15, a portion of a vascular assembly 368 according to various aspects of the present disclosure is provided. The vascular assembly 368 includes a housing 370 that defines a channel 372. The channel 372 extends along a longitudinal axis 374. Heat-transfer fluid may be circulated through the channel 372 to absorb heat from a heat source 376. The channel 372 defines a substantially circular shape perpendicular to the longitudinal axis 374.

Referring to FIG. 16, a portion of a vascular assembly 382 according to various aspects of the present disclosure is provided. The vascular assembly 382 includes a housing 384 that defines the channel 386. The channel 386 extends along the longitudinal axis 388. Heat-transfer fluid may be circulated to the channel 386 to absorb heat from a heat source 390. The channel 386 defines a substantially triangular shape perpendicular to the longitudinal axis 388. The base 392 of the triangle is disposed toward the heat source 390. Compared to a circular channel (see, e.g., channel 372 of FIG. 15) the arrangement of the base 392 of the triangle near the heat source 390 results in increased heat transfer. Furthermore, the triangular-shaped yields a reduction in pressure drop through the channel 386 due to an increase in volume provided an upper portion 394 of the channel 386 (as compared to a channel having a smaller volume).

With reference to FIG. 17, a portion of vascular assembly 402 according to various aspects of the present disclosure is provided. Vascular assembly 402 includes housing 404 that defines a channel 406. The channel 406 extends along the longitudinal axis 408. A heat-transfer fluid may be circulated through the channel 406 to absorb heat from a heat source 410. The channel 406 may define a substantially rectangular cross-sectional shape perpendicular to the longitudinal axis 408. The rectangular shape may include rounded corners 412. The rectangular cross-section may define a width 414 and a height 416. The width 414 may be greater than the height 416. Compared to a circular channel (see, e.g., channel 372 of FIG. 15), the rectangular channel may yield increased heat transfer and decreased structural performance.

Referring to FIG. 18, a portion of a vascular assembly 420 according to various aspects of the present disclosure is provided. The vascular assembly 420 may include a housing 422 that defines the channel 424. The channel 424 may extend along a longitudinal axis 426. A heat-transfer fluid may be circulated to the channel 424 to absorb heat from a heat source 428. The channel 424 may define a substantially elliptical shape in a direction perpendicular to the longitudinal axis 426. The elliptical shape may define a width 430 and a height 432. The width 430 may be greater than the height 432. Compared to a circular channel (see, e.g., channel 372 of FIG. 15), the elliptical cross-section may have increased heat transfer performance and increased structural performance.

With reference to FIG. 19, a portion of a vascular assembly 440 according to various aspects of the present disclosure is provided. The vascular assembly 440 may include a housing 442 that defines the channel 444. The channel 444 may extend along the longitudinal axis 446. A heat-transfer fluid may be circulated through the channel 444 to absorb heat from a heat source 448. The channel 444 may define a substantially star-shaped cross-section in a direction perpendicular to the longitudinal axis 446. The star-shaped cross-section may include sixteen points 450. Compared to a circular channel (see, e.g., channel 372 of FIG. 15), the star-shaped cross-section may have increased heat transfer performance.

Referring to FIG. 20, a portion of yet another vascular assembly 460 according to various aspects of the present disclosure is provided. The vascular assembly 460 includes a housing 462 that defines the channel 464. The channel 464 extends along the longitudinal axis 466. A heat-transfer fluid may be circulated through the channel 464 to absorb heat from a heat source 468. The channel 464 may define a substantially star-shaped cross-section in a direction perpendicular to the longitudinal axis 466. The star-shaped cross-section may include sixteen points 470. Compared to the star-shaped cross-section of the channel 444 of FIG. 19, the star-shaped cross-section of the channel 464 of FIG. 20 may have longer points 470. Compared to a circular cross-section (see, e.g., channel 372 of FIG. 15), the star-shaped cross-section may have increased heat transfer properties.

Referring to FIG. 21, a portion of yet another vascular assembly 480 according to various aspects of the present disclosure is provided. The vascular assembly 480 includes a housing 482 that defines a channel 484. The channel 484 extends along a longitudinal axis 486. The channel 484 may include a coating or shell 488. In various aspects, the shell 488 may add rigidity to the channel 484. In various aspects, the shell may decrease a roughness of a surface in contact with a heat-transfer fluid within the channel 484 (e.g., by eliminating a porosity of a sacrificial material from which the channel is formed). In various aspects, the shell 488 is a protective shell.

The shell 488 may define a thickness 490. The thickness 490 may be greater than or equal to about 1 μm to less than or equal to about 1 mm. The shell 488 may be formed from a metal, a polymer, a polymeric composite, or a combination thereof. A heat-transfer fluid may be circulated through the channel 484 to absorb heat from a heat source 492. The heat-transfer fluid may be in fluid communication with an inner surface 494 of the shell 488.

Methods of Manufacturing Vascular Assemblies

In various aspects, the present disclosure provides a method of manufacturing a vascular assembly. In general, the method includes (1) forming a channel precursor; (2) forming an intermediate assembly including the channel precursor and at least one thermally-conductive element; (3) forming a solid polymeric assembly including the intermediate assembly; and (4) removing the channel precursor to form the vascular assembly defining a channel. The vascular assembly includes the channel in fluid communication with the thermally-conductive element.

1. Forming a Channel Precursor

The channel precursor may be used to facilitate the formation of one or more channels in the vascular assembly. The channel precursor is formed from a sacrificial material that can be removed from the vascular assembly after the housing is formed. The channel precursor may define a geometry of the channel. For example, the channel precursor may define a star-shaped cross-section perpendicular to a longitudinal axis of the channel precursor to form a channel having the star-shaped cross-section.

The sacrificial material may include a material that is capable of one or more of: melting, vaporizing, combusting, and solubilizing. Examples of suitable sacrificial materials include metals, polymers, combustible materials, and combinations thereof. Metals may include solders, such as solders including lead, tin, zinc, aluminum, suitable alloys, and the like, by way of example. Polymers may include polyvinyl acetate, polylactic acid, polyethylene, polystyrene, by way of example. Combustible materials may include ceramics, salts (e.g., potassium nitrate), black powder, charcoal, pentaerythritol tetranitrate, combustible metals, combustible oxides, thermites, nitrocellulose, pyrocellulose, flash powders, smokeless powder, and combinations thereof, by way of example. Additionally or alternatively, the sacrificial material may be treated with a catalyst or chemically modified to alter melting or degradation behavior.

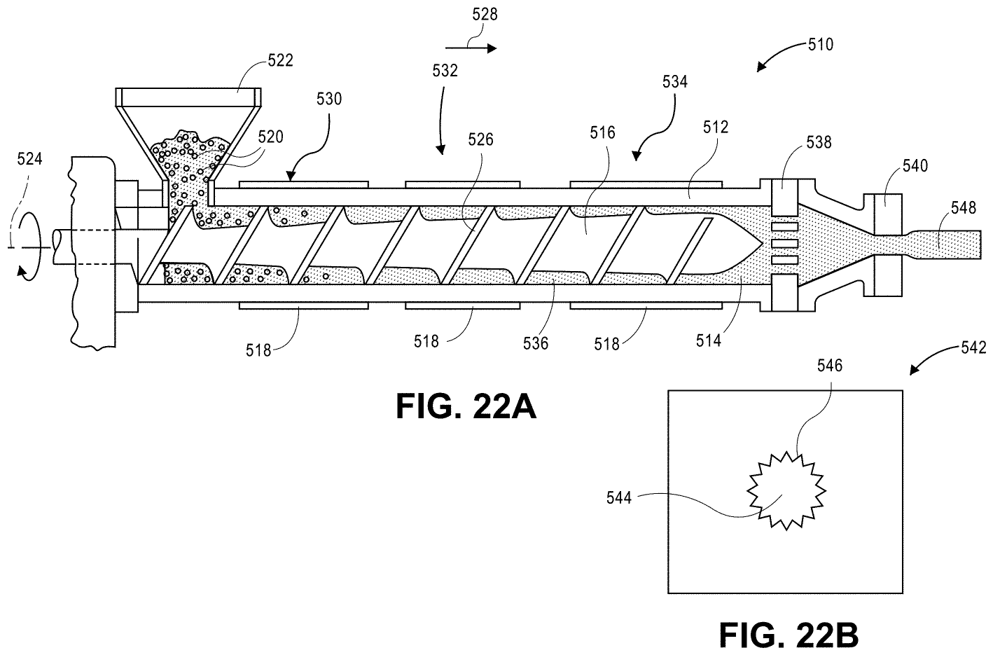

In one example, the channel precursor is formed by extrusion. With reference to FIGS. 22A-22B, an extruder 510 for forming a channel precursor according to various aspects of the present disclosure is provided. The extruder 510 includes a barrel 512, which may be substantially cylindrical. The barrel 512 defines a chamber 514 into which a screw 516 is disposed. A plurality of heaters 518 are disposed around an outside of the barrel 512.

A plurality of pellets 520 comprising a sacrificial material may be added to a hopper 522 of the extruder 510. The pellets 520 enter the chamber 514, for example under the force of gravity. The screw 516 rotates about a longitudinal axis 524, and a plurality of threads 526 of the screw 516 direct the pellets 520 through the chamber 514 in a direction 528. More particularly, the screw 516 forces the pellets 520 through a feed section 530, then a compression section 532, and then a metering section 534. As the pellets 520 travel through the chamber 514, they are melted to form a polymer melt 536. The polymer melt 536 flows through a breaker plate 538 and into a die 540. The die 540 includes a die plate 542 having an aperture 544. A perimeter 546 of the aperture 544 is sized and shaped according to a desired channel size and shape. The polymer melt is forced through the aperture 544 of the die plate 542 to form an extrudate 548. All or a portion of the extrudate 548 can be used as a channel precursor.

In various aspects, a shell or coating may be formed around the channel precursor shell (see, e.g., outer shell 488 of FIG. 21) after the channel precursor is formed. When the channel precursor includes an outer shell, the sacrificial material may also be a gas, such as air.

2. Forming an Intermediate Assembly

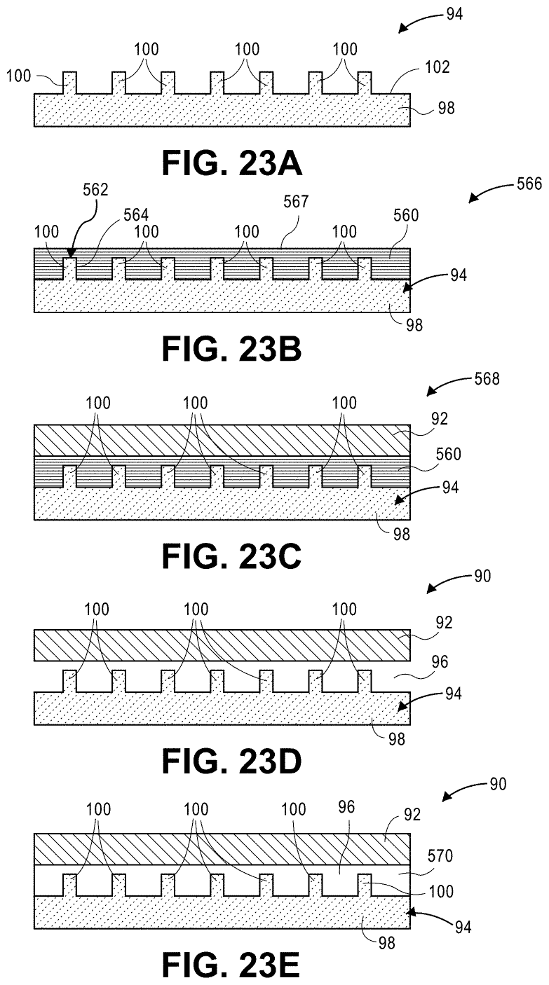

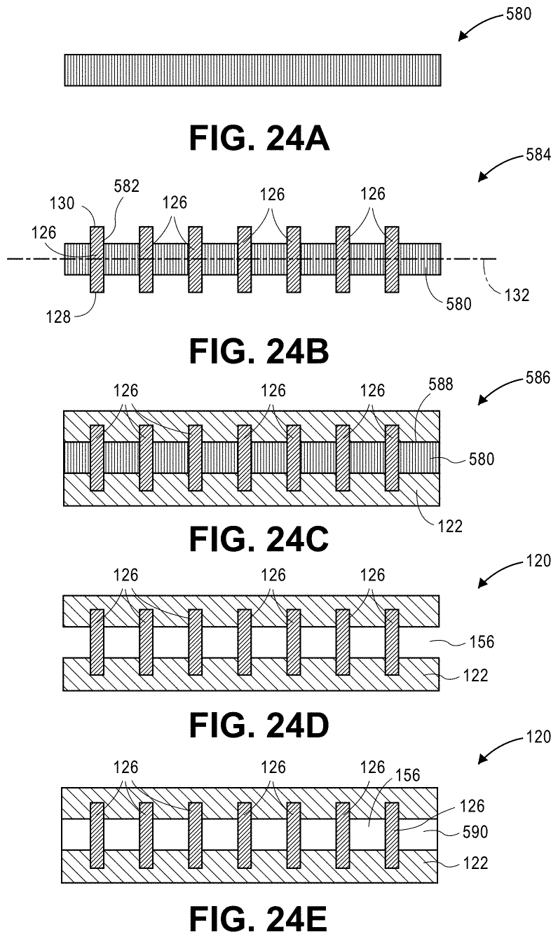

Forming an intermediate assembly includes assembling one or more thermally-conductive elements to the channel precursor. Forming an intermediate assembly including protrusions as the thermally-conductive element includes piercing the channel precursor (and optionally, the shell) with the protrusions so that the protrusions extend at least partially through the channel precursor, as described in greater detail below (FIG. 23B). Forming an intermediate assembly including pins as the thermally-conductive element includes piercing the channel precursor (and optionally, the shell) with the pins so that the pins extend at least partially into the channel precursor, as described in greater detail below (FIG. 24B). Forming an intermediate assembly including a sheath includes applying the sheath to an outer surface of the channel precursor (or optional shell), as described in greater detail below (FIG. 25B).

3. Forming a Solid Polymeric Assembly

Forming a solid polymeric assembly includes at least partially enclosing the channel within a housing. When the housing includes a polymer or a reinforced composite, the housing can be formed by molding. Molding includes placing the intermediate assembly in a mold. Molding further includes introducing a housing precursor into the mold. The housing precursor includes a polymer precursor. When a reinforced composite is to be formed, the housing precursor also includes a plurality of reinforcing fibers or particles. The method further includes solidifying the housing precursor to form the solid polymeric assembly. In the solid polymeric assembly, the housing is disposed around at least a portion of the channel precursor.

4. Removing the Channel Precursor to Create the Vascular Assembly

The channel precursor including the sacrificial material is removed from the polymeric assembly to create the vascular assembly having the channel. The removing may optionally include providing access to the channel precursor material (e.g., by drilling into the housing) to provide access to the channel precursor. The channel precursor may be removed by one or more of volatilizing, melting, combusting, or degrading the sacrificial material, or by dissolving the sacrificial material to produce degradants.

In one example, the sacrificial material is heated to a temperature (e.g., greater than or equal to about 150° C. to less than or equal to about 200° C.) to melt or vaporize the sacrificial material. The temperature may be selected to effectively remove the sacrificial material without damaging the housing. In another example, the sacrificial material is subjected to a reaction to deflagrate the sacrificial material without degrading the polymer or optional reinforcement of the housing. In yet another example, a solvent (e.g., acetone) is applied, optionally with agitation, to dissolve the sacrificial material without damaging the housing. In yet another example, the sacrificial material is etched using a suitable acid (e.g., hydrochloric acid, sulfuric acid, nitric acid, and the like).

Method A: Forming a Channel Having Protrusions

With reference to FIGS. 23A-23B, a method of forming a channel having protrusions according to various aspects of the present disclosure is provided. The method is described in the context of the vascular assembly 90 of FIGS. 4A-4B. At FIG. 23A, the method includes providing the thermally-conductive component 94 having the body 98, which may plated-shaped, and the protrusions 100. The thermally-conductive component may include GRIP Metal™.

At FIG. 23B, a first channel precursor 560 is assembled to the thermally-conductive component 94. More particularly, distal ends 562 of the protrusions 100 are inserted or pierced into the first channel precursor 560 so that outer surfaces 564 of the protrusions are in direct communication with the first channel precursor 560. The engagement of the protrusions 100 with the first channel precursor 560 may facilitate better control of the placement of the first channel precursor 560 on the thermally-conductive component 94. The protrusions 100 may be inserted into the first channel precursor 560 until the first channel precursor 560 is in direct communication with the surface 102 of the body 98 of the thermally-conductive component 94. Thus, a first intermediate assembly 566 including the first channel precursor 560 and the thermally-conductive component 94 is formed.

At FIG. 23C, the method includes forming a first solid polymeric assembly 568. Forming the first solid polymeric assembly 568 includes at least partially enclosing the first channel precursor 560 within the housing 92, as described in above at step 3. In various aspects, the first channel precursor 560 may be fully enclosed within the housing 92. At FIG. 23D, the first channel precursor 560 is removed from the first solid polymeric assembly 568 to create the channel 96 of the vascular assembly 90, as described above at step 4. At FIG. 23E, a heat-transfer fluid 570 is circulated through the channel 96.

Method B: Forming a Channel Having Pins

With reference to FIGS. 24A-24B, a method of forming a channel having pins according to various aspects of the present disclosure is provided. The method is described in the context of the vascular assembly 120 of FIGS. 5A-5B. At FIG. 24A, the method includes providing a second channel precursor 580 including a sacrificial material.

At FIG. 24B, the plurality of columns or pins 126 is assembled to the second channel precursor 580. The first or second end 128, 130 of each pin 126 may be inserted into the second channel precursor 580 so that each of the first and second ends 128, 130 extends outside of the second channel precursor 580. In one example, a device is used to concurrently press the pins 126 into the second channel precursor 580. In another example, the pins 126 are inserted in the second channel precursor 580 in line with formation of the second channel precursor 580 (e.g., as the second channel precursor 580 exits the extruder, as described above).

At FIG. 24C, the method includes forming a second solid polymeric assembly 586. Forming the second solid polymeric assembly 586 includes at least partially enclosing the second channel precursor 580 within the housing 122, as described above at step 3, so that an outer surface 588 of the second channel precursor 580 is in direct contact with the housing 122. At FIG. 24D, the second channel precursor 580 is removed from the second solid polymeric assembly 586 to create the channel 156 of the vascular assembly 120, as described above at step 4. At FIG. 24E, a heat-transfer fluid 590 is circulated through the channel 156.

Method C: Forming a Channel Having a Sheath

With reference to FIGS. 25A-25E, a method of forming a channel having a sheath according to various aspects of the present disclosure is provided. The method is described in the context of the vascular assembly 150 of FIGS. 6A-6B. At FIG. 25A, the method includes providing a third channel precursor 600 including a sacrificial material.

At FIG. 25B, the method includes applying the sheath 154 to an outer surface 602 of the third channel precursor 600 to form a third intermediate assembly 604. In one example, the sheath includes the coil 154 that is formed by winding a thread or wire around the outer surface 602 of the third channel precursor 600. In various aspects, the coil 154 is at least partially inserted into the third channel precursor 600 to form fins or corrugation. In another example, a sheath is a braided tube (not shown) that is formed by braiding a plurality of threads or wires around the outer surface 602 of the third channel precursor. In yet another example, a sheath is a mesh tube (not shown) that is formed by applying a mesh sheet around the outer surface 602 of the third channel precursor 600. In yet another example, a sheath is knitted or crocheted around the outer surface 602 of the third channel precursor 600. In yet another example, a sheath is a thermally-conductive polymeric coating with ribs, such as axial ribs, circumferential ribs, or spiraled ribs.

At FIG. 25C, the method includes forming a third solid polymeric assembly 606. Forming the third solid polymeric assembly 606 includes at least partially enclosing the third channel precursor 600 within the housing 152, as described above at step 3. In various aspects, forming the third solid polymeric assembly 606 may include fully enclosing the third channel precursor 600 in the housing 152. At FIG. 24D, the third channel precursor 600 is removed from the third solid polymeric assembly 606 to create the channel 156 of the vascular assembly 150, as described above at step 4. At FIG. 25E, a heat-transfer fluid 608 is circulated through the channel 156.

### EXAMPLES

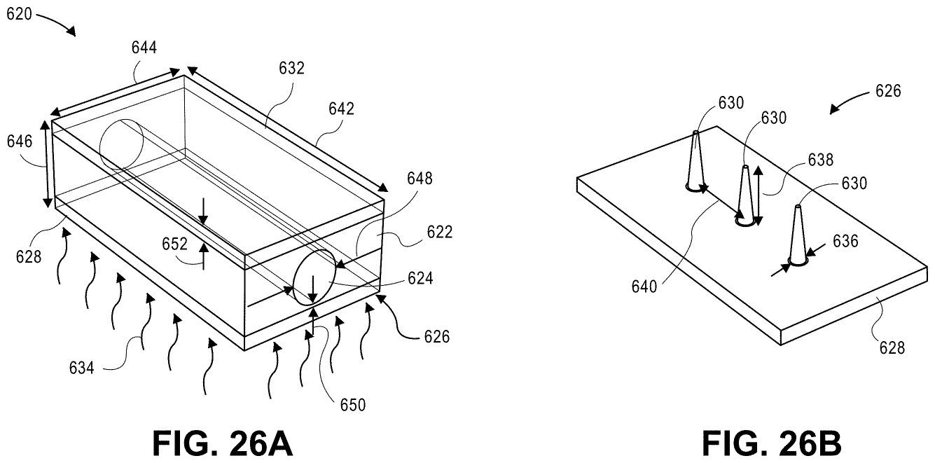

With reference to FIGS. 26A-26B, a vascular assembly 620 according to various aspects of the present disclosure is provided. The vascular assembly 620 includes a housing 622 that defines a channel 624. The vascular assembly 620 further includes a thermally-conductive component 626 having a body 628 and a plurality of thermally-conductive elements 630, which are protrusions. The thermally-conductive elements 630 extend into the channel 624. The vascular assembly 620 further includes a heat spreader plate 632. The channel 624 is disposed between the thermally-conductive component 626 and the heat spreader plate 632. A heat source 634 is in thermal contact with the thermally-conductive component 626. The heat source 634 supplies a power of about 10 W.

The thermally-conductive component 626 and the heat spreader plate 632 are formed from aluminum. The housing 622 is formed from a polymer. A heat-transfer fluid that includes ethylene glycol and water at a 50/50 ratio by volume is circulated through the channel 624 to absorb heat from the heat source 634. Each heat-transfer element 630 defines a diameter 636 that is measured adjacent to the body 628 and a height 638 measured substantially perpendicular to the diameter 636. The thermally-conductive elements 630 are spaced apart from one another by a protrusion spacing 640, which is a distance between respective centers of each protrusion 630.

The vascular assembly 620 defines a length 642, a width 644 substantially perpendicular to the length 642, and a height 646 substantially perpendicular to the length 642 and the width 644. The channel 624 extends along a longitudinal axis (not shown) and defines a substantially circular cross-section perpendicular to the longitudinal axis. The channel 624 defines a diameter 648. A body-to-channel separation 650 is a minimum distance between the channel 624 and the body 628 of the thermally-conductive component 626 measured substantially parallel to the height 646. Each of the body 628 and the heat spreader plate 632 defines a thickness 652. The properties described in Table 1 apply in each of the Examples 1-8.

TABLE 1

| Property | Value |
|---|---|
| Vascular Assembly Length | 10.4 mm |
| Vascular Assembly Width | 5.4 mm |
| Vascular Assembly Height | 2 mm |
| Channel Diameter | 1.8 mm |
| Protrusion Diameter | ⅓ · Protrusion Height |
| Heat-transfer Fluid Flow Rate | 260 mm/s |
| Heat-transfer Fluid Temperature | 40° C. |
| Heat Source Power | 10 W |

### Example 1: Effect of Protrusions with Low Conductivity Polymer

Vascular assemblies A and B each include a polymer having a thermal conductivity of 0.6 W/m·K. Vascular Assembly A includes protrusions as a heat-transfer element (e.g., heat-transfer element 630 of FIGS. 26A-26B). Vascular Assembly B excludes protrusions and does not have a heat-transfer element. When subjected to the heat source 634, a global max temperature of Vascular Assembly A (123° C.) is significantly less than a global max temperature of Vascular Assembly B (261° C.), as shown in Table 2 below. Thus, the presence of the heat-transfer elements has a significant effect on global maximum temperature and heat transfer when the thermal conductivity of the polymer is relatively low.

TABLE 2

| | Vascular | |
|---|---|---|
| Property | Assembly A | Vascular Assembly B |
| Spreader Thickness | 0.5 mm | 0.5 mm |
| Polymer Thermal Conductivity | 0.6 W/m · K | 0.6 W/m · K |
| Spreader to Channel Separation | 0.25 mm | 0.25 mm |
| Protrusions Present? | Yes | No |
| Protrusion Spacing | 2.5 mm | NA |
| Protrusion Height | 1.4 mm | NA |
| Protrusion Diameter | Height/3 | NA |
| Global Max Temperature | 123° C. | 261° C. |

### Example 2: Effect of Protrusions with High Conductivity Polymer

Vascular Assemblies C and D each include a polymer having a thermal conductivity of 5 W/m·K. Vascular Assembly C includes protrusions as a heat-transfer element (e.g., heat-transfer element 630 of FIGS. 26A-26B). Vascular Assembly B excludes protrusions and does not have a heat-transfer element. When subjected to the heat source 634, a global max temperature of Vascular Assembly C (74° C.) is similar, but less than a global max temperature of Vascular Assembly D (79° C.), as shown in Table 3 below. The presence of the heat-transfer elements has a less significant effect on global max temperature and heat transfer when the thermal conductivity of the polymer is relatively high, as compared to when the thermal conductivity of the polymer is relatively low (e.g., as in Example 1).

TABLE 3

| | Vascular | |
|---|---|---|
| Property | Assembly C | Vascular Assembly D |
| Spreader Thickness | 0.5 mm | 0.5 mm |
| Polymer Thermal Conductivity | 5 W/m · K | 5 W/m · K |
| Spreader to Channel Separation | 0.25 mm | 0.25 mm |
| Protrusions Present? | Yes | No |
| Protrusion Spacing | 2.5 mm | NA |
| Protrusion Height | 1.4 mm | NA |
| Protrusion Diameter | Height/3 | NA |
| Global Max Temperature | 74° C. | 79° C. |

### Example 3: Effect of Protrusion Spacing and Height

Vascular Assembly E and Vascular Assembly F each include GRIP Metal™ as the thermally-conductive component 626. Vascular Component E includes “Mini” size GRIP Metal™ and Vascular Assembly F includes “Nano” size GRIP Metal™. Vascular Assembly E, which includes larger protrusions having a greater protrusion spacing 640 than Vascular Assembly F, has a lower global maximum temperature (123° C.) than a global maximum temperature of Vascular Assembly F (150° C.), as shown in Table 4 below. Thus, larger, spaced apart protrusions may facilitate a higher rate of heat transfer than smaller, closer spaced protrusions.

TABLE 4

| | Vascular | |
|---|---|---|
| Property | Assembly E | Vascular Assembly F |
| Spreader Thickness | 0.5 mm | 0.5 mm |
| Polymer Thermal Conductivity | 0.6 W/m · K | 0.6 W/m · K |
| Spreader to Channel Separation | 0.25 mm | 0.25 mm |
| Protrusions Present? | Yes | Yes |
| Protrusion Spacing | 2.5 mm | 1 mm |
| Protrusion Height | 1.4 mm | 0.7 mm |
| Protrusion Diameter | Height/3 | Height/3 |
| Global Max Temperature | 123° C. | 150° C. |

### Example 4: Effect of Protrusion Height

Vascular Assembly G includes longer protrusions than Vascular Assembly H, as shown in Table 5 below. Vascular Assembly G has a lower global maximum temperature (123° C.) than a global maximum temperature of Vascular Assembly H (185° C.). Thus, longer protrusions may facilitate a greater rate of heat transfer than shorter protrusions.

TABLE 5

| | Vascular | |
|---|---|---|
| Property | Assembly G | Vascular Assembly H |
| Spreader Thickness | 0.5 mm | 0.5 mm |
| Polymer Thermal Conductivity | 0.6 W/m · K | 0.6 W/m · K |
| Spreader to Channel Separation | 0.25 mm | 0.25 mm |
| Protrusions Present? | Yes | Yes |
| Protrusion Spacing | 2.5 mm | 2.5 mm |
| Protrusion Height | 1.4 mm | 0.7 mm |
| Protrusion Diameter | Height/3 | Height/3 |
| Global Max Temperature | 123° C. | 185° C. |

### Example 5: Effect of Heat Spreader Thickness

Vascular Assembly I defines a greater spreader thickness 652 than Vascular Assembly J, as shown in Table 6 below. Vascular Assembly I has a similar global maximum temperature (123° C.) as a global maximum temperature of Vascular Assembly J (127° C.). Thus, spreader thickness 652 may have only a minimal effect on rate of heat transfer.

TABLE 6

| | Vascular | |
|---|---|---|
| Property | Assembly I | Vascular Assembly J |
| Spreader Thickness | 0.5 mm | 0.3 mm |
| Polymer Thermal Conductivity | 0.6 W/m · K | 0.6 W/m · K |
| Spreader to Channel Separation | 0.25 mm | 0.25 mm |
| Protrusions Present? | Yes | Yes |
| Protrusion Spacing | 2.5 mm | 2.5 mm |
| Protrusion Height | 1.4 mm | 1.4 mm |
| Protrusion Diameter | Height/3 | Height/3 |
| Global Max Temperature | 123° C. | 127° C. |

### Example 6: Effect of Housing Polymer Thermal Conductivity

Vascular Assemblies K, L, M, and N include polymers having different thermal conductivities, as shown in Table 7 below. Global maximum temperature generally decreases as polymer thermal conductivity increases. Higher polymer thermal conductivities can yield higher rates of heat transfer than lower thermal conductivities. Therefore, even with the heat-transfer element, thermal conductivity of the polymer of the housing 622 still has an effect on rate of heat transfer.

TABLE 7

| | | Vascular | | |
|---|---|---|---|---|
| | Vascular | Assembly | Vascular | Vascular |
| Property | Assembly K | L | Assembly M | Assembly N |
| Spreader | 0.5 mm | 0.5 mm | 0.5 mm | 0.5 mm |
| Thickness | | | | |
| Polymer Thermal | 0.6 W/m · K | 5 W/m · K | 0.2 W/m · K | 1.5 W/m · K |
| Conductivity | | | | |
| Spreader to | 0.25 mm | 0.25 mm | 0.25 mm | 0.25 mm |
| Channel | | | | |
| Separation | | | | |
| Protrusions | Yes | Yes | Yes | Yes |
| Present? | | | | |
| Protrusion | 2.5 mm | 2.5 mm | 2.5 mm | 2.5 mm |
| Spacing | | | | |
| Protrusion Height | 1.4 mm | 1.4 mm | 1.4 mm | 1.4 mm |
| Protrusion | Height/3 | Height/3 | Height/3 | Height/3 |
| Diameter | | | | |
| Global Max | 123° C. | 74° C. | 141° C. | 100° C. |
| Temperature | | | | |

### Example 7: Effect of Heat Spreader Spacing with Protrusions

Vascular Assemblies O and P include protrusions as a heat-transfer element. Vascular Assembly O defines a larger body-to-channel separation 650 than Vascular Assembly P, as shown in Table 8 below. Vascular Assembly O has a higher global maximum temperature (123° C.) than a global maximum temperature of Vascular Assembly P (100° C.). Therefore, decreasing the body-to-channel separation 650 can increase a rate of heat transfer.

TABLE 8

| | Vascular | |
|---|---|---|
| Property | Assembly O | Vascular Assembly P |
| Spreader Thickness | 0.5 mm | 0.5 mm |
| Polymer Thermal Conductivity | 0.6 W/m · K | 0.6 W/m · K |
| Spreader to Channel Separation | 0.25 mm | 0.05 mm |
| Protrusions Present? | Yes | Yes |
| Protrusion Spacing | 2.5 mm | 1 mm |
| Protrusion Height | 1.4 mm | 0.7 mm |
| Protrusion Diameter | Height/3 | Height/3 |
| Global Max Temperature | 123° C. | 100° C. |

### Example 8: Effect of Heat Spreader Spacing without Protrusions

Vascular Assemblies Q and R do not include thermally-conductive elements. Vascular Assembly Q defines a larger body-to-channel separation 650 than Vascular Assembly R, as shown in Table 9 below. Vascular Assembly Q has a higher global maximum temperature (261° C.) than a global maximum temperature of Vascular Assembly R (170° C.). Therefore, decreasing the body-to-channel separation 650 can increase a rate of heat transfer when a heat-transfer element is not present.

TABLE 9

| | Vascular | |
|---|---|---|
| Property | Assembly Q | Vascular Assembly R |
| Spreader Thickness | 0.5 mm | 0.5 mm |
| Polymer Thermal Conductivity | 0.6 W/m · K | 0.6 W/m · K |
| Spreader to Channel Separation | 0.25 mm | 0.05 mm |
| Protrusions Present? | No | No |
| Protrusion Spacing | NA | NA |
| Protrusion Height | NA | NA |
| Protrusion Diameter | NA | NA |
| Global Max Temperature | 261° C. | 170° C. |

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1-20. (canceled)

21. A method of manufacturing a channel having a thermally-conductive element for heat transfer, wherein the method comprises:
(a) forming an intermediate assembly by engaging a thermally-conductive element with a channel precursor, the channel precursor comprising a sacrificial material, the thermally-conductive element comprising a thermally-conductive material;
(b) forming a housing comprising:
placing the intermediate assembly in a mold;
introducing a housing precursor into the mold, the housing precursor comprising a polymer precursor; and
solidifying the polymer precursor to form a solid polymeric assembly comprising a polymeric housing disposed around at least a portion of the channel precursor; and
(c) removing the sacrificial material to form a channel comprising the thermally-conductive element, wherein the channel is at least partially defined by the polymeric housing.

22. The method of claim 21, wherein the thermally-conductive element comprises a plurality of thermally-conductive elements.

23. The method of claim 22, wherein the forming the intermediate assembly comprises piercing the channel precursor with the plurality of thermally-conductive elements.

24. The method of claim 22, wherein the plurality of thermally-conductive elements extend along at least a portion of a diameter of the channel.

25. The method of claim 22, wherein the plurality of thermally-conductive elements extend along an entire diameter of the channel.

26. The method of claim 22, wherein the plurality of thermally-conductive elements comprises a plurality of protrusions.

27. The method of claim 22, wherein the plurality of thermally-conductive elements comprises a plurality of pins.

28. The method of claim 21, wherein the forming the intermediate assembly comprises applying the thermally-conductive element circumferentially around at least a portion of an outer surface of the channel precursor.

29. The method of claim 28, wherein the thermally-conductive element comprises one or more of a coil, a braided tube, a mesh tube, a knitted tube, or a crocheted tube.

30. The method of claim 22, wherein the plurality of thermally-conductive elements extend from a body comprising the thermally-conductive material.

31. The method of claim 30, wherein the channel is at least partially defined by the polymeric housing and the body.

32. The method of claim 21, wherein the housing precursor further comprises at least one of (a) a plurality of reinforcing fibers or (b) a plurality of reinforcing particles.

33. The method of claim 32, wherein the plurality of reinforcing fibers or the plurality of reinforcing particles is thermally conductive.

34. The method of claim 21, wherein the removing comprises one or more of: melting, vaporizing, combusting, or solubilizing the sacrificial material.

35. The method of claim 21, wherein the thermally-conductive material comprises a metal material, a ceramic material, or a combination thereof.

36. The method of claim 21, wherein the channel defines a diameter of greater than or equal to about 100 μm to less than or equal to about 10 mm.

37. The method of claim 21, wherein the channel has an open volume of at least about 40% of a total volume of the channel.

38. The method of claim 21, further comprising forming the channel precursor, the channel precursor extending along a longitudinal axis and defining a cross-sectional shape substantially perpendicular to the longitudinal axis, the cross-sectional shape being selected from the group consisting of a circular shape, a triangular shape, an elliptical shape, a rectangular shape, and a multipoint star shape.

39. The method of claim 38, wherein the cross-sectional shape is selected from the group consisting of the triangular shape, the rectangular shape, and the multipoint star shape.

40. The method of claim 38, wherein the forming the channel precursor comprises extrusion.
